(19) United States
(12) Patent Application Publication
(10) Pub. No.: US 2014/0048947 A1
(43) Pub. Date: Feb. 20, 2014

(54) SYSTEM PACKAGE

(71) Applicant: SK HYNIX INC., Icheon-si (KR)

(72) Inventors: Dong Uk LEE, Icheon-si (KR); Dong Uk Lee, Icheon-si (KR); Sang Hoon Shin, Icheon-si (KR)

(73) Assignee: SK hynix Inc., Icheon-si (KR)

(21) Appl. No.: 13/720,533

(22) Filed: Dec. 19, 2012

(30) Foreign Application Priority Data
Aug. 20, 2012 (KR) 10-2012-0090718

(51) Int. Cl. H01L 23/538

(52) U.S. Cl. CPC H01L 23/5384
USPC 257/774; 257/786; 257/777

(57) ABSTRACT

A system package includes an interposer, a control chip mounted onto the interposer, and first and second semiconductor chips mounted onto the interposer and electrically coupled to the control chip through the interposer. The first and second chips are configured to operate under the control of the control chip. The first semiconductor chip is positioned along one side of the control chip, and the second semiconductor chip is positioned along another side of the control chip.

### CROSS-REFERENCES TO RELATED APPLICATION

The present application claims priority under 35 U.S.C. §119(a) to Korean application number 10-2012-0090718 filed on Aug. 20, 2012 in the Korean Intellectual Property Office, which is incorporated herein by reference in its entirety.

### BACKGROUND

1. Technical Field

The present invention relates to a system package, and more particularly, to a structure of a system package.

2. Related Art

The packaging technology for semiconductor integrated circuits has continuously evolved in order to satisfy the demand for miniaturization and performance improvement, and research has been conducted on multi-chip packaging in which a number of semiconductor chips are included in a single package.

Among the multi-chip packages, much attention has been paid to a system package in which a plurality of semiconductor chips having different functions are included in a single package, thereby implementing a system. That is, the system package represents a complete system included in one package. Specifically, the system package may be a multi-chip module (MCM) that includes a microprocessor, a plurality of chips, and other components of a complete system.

FIG. 1 is a cross-sectional view of a conventional system package.

The system package illustrated in FIG. 1 includes an interposer 10, a control chip 20, and a memory chip 30.

The control chip 20 may operate as a microprocessor and serves to control the operation of the memory chip 30.

The memory chip 30 serves to store data under the control of the control chip 20.

In the system package, the control chip 20 and the memory chip 30 are required to be closely interconnected in order to ensure high-speed operation. However, the control chip 20 and the memory chip 30 are difficult to directly connect through a conductive wire, because of the length limit of the conductive wire. Therefore, the control chip 20 and the memory chip 30 are mounted onto the interposer 10 and electrically connected to each other through the interposer 10. The control chip 20 and the memory chip 30 may be mounted onto the interposer 10 through micro bumps 22 and 32, respectively.

The interposer 10 may include a semiconductor substrate with conductive interconnect lines 11 over the semiconductor substrate. The control chip 20 and the memory chip 30 are electrically connected to one another through the conductive interconnect lines 11. The interposer 10 is electrically connected to one or more external components through one or more bumps 12.

In the conventional system package illustrated in FIG. 1, the control chip 20 and the memory chip 30 are mounted in close proximity along a top side of the interposer 10. Furthermore, each of the control chip 20 and the memory chip 30 includes an interface block 21 and 31 formed in areas of the respective chips adjacent to each other so as to minimize the distance over which signals travel between the chips. The interface block includes an input/output buffer, an input/output pad and the like, to accommodate the signal input/output operation.

Therefore, power consumption may be concentrated at the interface blocks 21 and 31 of the control chip 20 and the memory chip 30, thereby causing power drop and excessive heat. The excessive heat may degrade the performance of the memory chip which is relatively vulnerable to heat, and thus reduce the reliability of the system package. Furthermore, as the number of interface lines increases with high integration of the system package, the size of the system package is inevitably increased.

Such problems may arise in any semiconductor chips controlled by the control chip 20 as well as the memory chip 30.

### SUMMARY

In accordance with one exemplary embodiment, a system package includes an interposer, a control chip mounted onto the interposer, and first and second semiconductor chips mounted onto the interposer and electrically coupled to the control chip through the interposer. The first and second chips are configured to operate under the control of the control chip. The first semiconductor chip is positioned along one side of the control chip, and the second semiconductor chip is positioned along another side of the control chip.

In another embodiment, a system package includes an interposer, a control chip mounted onto the interposer, and a plurality of semiconductor chips mounted onto the interposer and configured to operate under the control of the control chip. The plurality of semiconductor chips are positioned along four sides of the control chip.

In yet another embodiment, a system package includes an interposer, a control chip mounted onto the interposer, a first memory chip mounted onto the interposer along one side of the control chip and including a plurality of memory chips stacked on top of one another in a vertical direction. The first memory chip is configured to operate under the control of the control chip. A second memory chip mounted onto the interposer along another side of the control chip and including a plurality of memory chips stacked on top of one another in a vertical direction, the second memory chip being configured to operate under the control of the control chip.

### BRIEF DESCRIPTION OF THE DRAWINGS

Features, aspects, and embodiments are described in conjunction with the attached drawings, in which:

FIG. 1 is a cross-sectional view of a conventional system package;

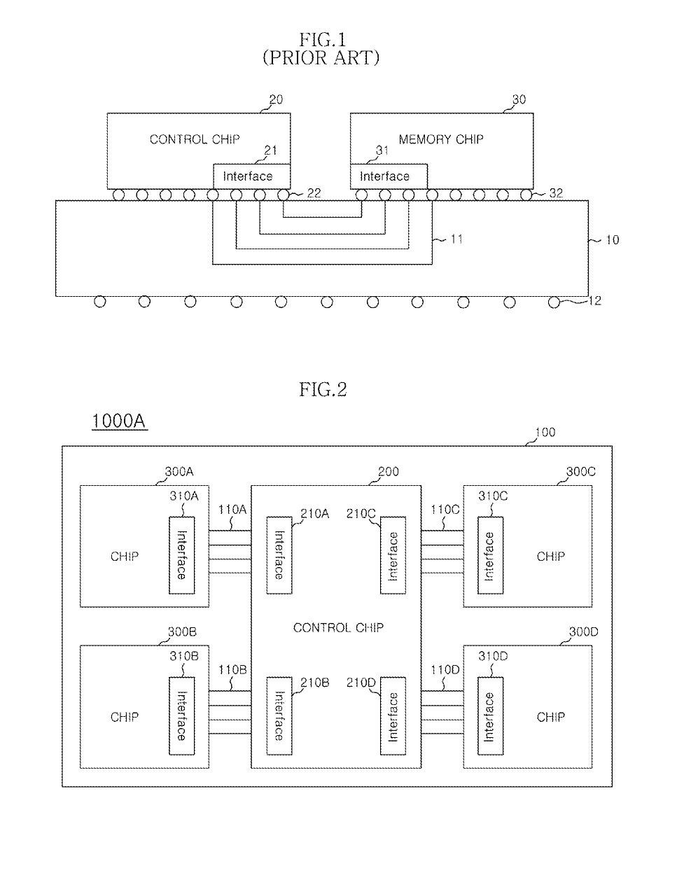

FIGS. 2 and 3 are plan views illustrating the structure of a system package according to exemplary embodiments;

FIG. 4 is a diagram illustrating a specific example of one of the semiconductor chips shown in FIGS. 2 and 3; and

FIG. 5 is a cross-sectional view illustrating the structure of a system package according to another exemplary embodiment.

### DETAILED DESCRIPTION

Hereinafter, exemplary embodiments of a system package will be described with reference to the accompanying drawings.

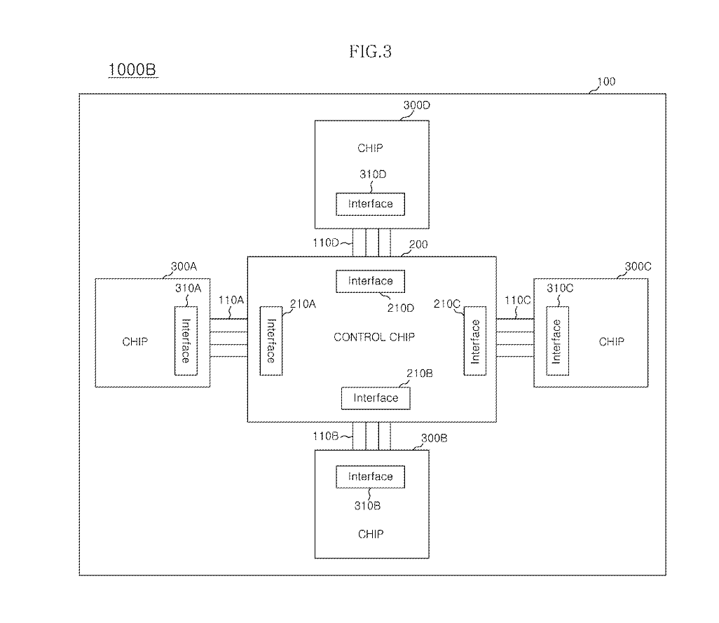

FIG. 2 is a plan view illustrating the structure of a system package 1000A according to one exemplary embodiment.

The system package 1000A may include an interposer 100, a control chip 200, and a plurality of semiconductor chips 300A to 300D having the same function and operating under the control of the control chip 200.

The interposer 100 may be a component for facilitating the electrical connection of heterogeneous chips in a semiconductor package. The interposer 100 may electrically connect the control chip 200 to the respective semiconductor chips 300A to 300D. In one embodiment, the interposer 100 may include a silicon chip serving an interface function and having metal interconnects without a semiconductor chip. In another embodiment, the interposer 100 may include a silicon chip serving an interface function and having a specific logic circuit.

The control chip 200 may be a microprocessor or memory controller that controls the operation of the semiconductor chips 300A to 300D. Desirably, the control chip 200 may be positioned in a center region of the interposer 100.

In one embodiment, the plurality of semiconductor chips 300A to 300D may be homogeneous semiconductor chips having the same function. For example, all of the semiconductor chips 300A to 300D may be configured as memory chips for storing data. The plurality of semiconductor chips 300A to 300D may be arranged over the interposer 100 so as to be distributed around the control chip 200. In one embodiment, the semiconductor chips 300A to 300D distributed around the control chip 200 include interface blocks 310A to 310D that are placed adjacent to corresponding interface blocks 210A to 210D in the control chip 200. The interface blocks 210A to 210D and 310A to 310D of the control chip 200 and the semiconductor chips 300A to 300D transmit and receive signals, and may include an input/output buffer and an input/output pad for performing signal input/output operations.

FIG. 2 illustrates that two semiconductor chips are arranged along the left and right sides of the control chip 200 however, the implementations are not limited thereto. The system package in accordance with some embodiments may be configured so that the semiconductor chips are distributed around a control chip to thereby reduce the congestion of interface blocks. This ensures that the power dissipation at the interface blocks is spread over a wider area.

However, it is desirable that the plurality of semiconductor chips 300A to 300D are arranged symmetrically with respect to the control chip 200 as illustrated in FIG. 2. As such, the left and right parts of the system may operate with the same electrical characteristics, and the semiconductor chips may be efficiently arranged without an empty space in terms of design.

Referring to FIG. 3, a system package 1000B according to another exemplary embodiment may be designed in such a manner that the semiconductor chips 300A to 300D are arranged along four sides of the control chip 200. The semiconductor chips 300A to 300D respectively include interface blocks 310A to 310D placed adjacent to corresponding ones of interface blocks 210A to 210D of the control chip 200. Therefore, in the case of the system package 1000B illustrated in FIG. 3, the interface areas are distributed along four sides of the control chip 200, thus spreading the power that dissipates at the interface blocks during operation.

The interposer 100 illustrated in FIG. 2 or 3 electrically connects the control chip 200 to the semiconductor chips 300A to 300D. In one embodiment, the interposer 100 includes a plurality of conductive interconnect lines 110A to 110D to electrically connect the control chip 200 and the respective semiconductor chips 300A to 300D. Specifically, the conductive interconnect lines 100A to 110D electrically connect the interface blocks 310A to 310D of the semiconductor chips 300A to 300D to the corresponding interface blocks 210A to 210D of the control chip 200, respectively.

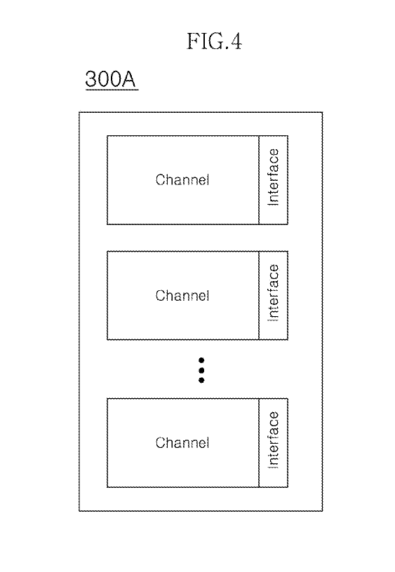

In one embodiment, each of the semiconductor chips 300A to 300D of FIG. 2 or 3 may include a memory chip having a plurality of channels to independently transmit and receive signals to and from the control chip 200. The memory chip includes the plurality of channels which may respectively have signal transfer unit (not shown) each operating independently. Referring to FIG. 4, one memory chip 300A may include a plurality of independent channels, and each of the channels may have an independent interface for transmitting and receiving signals.

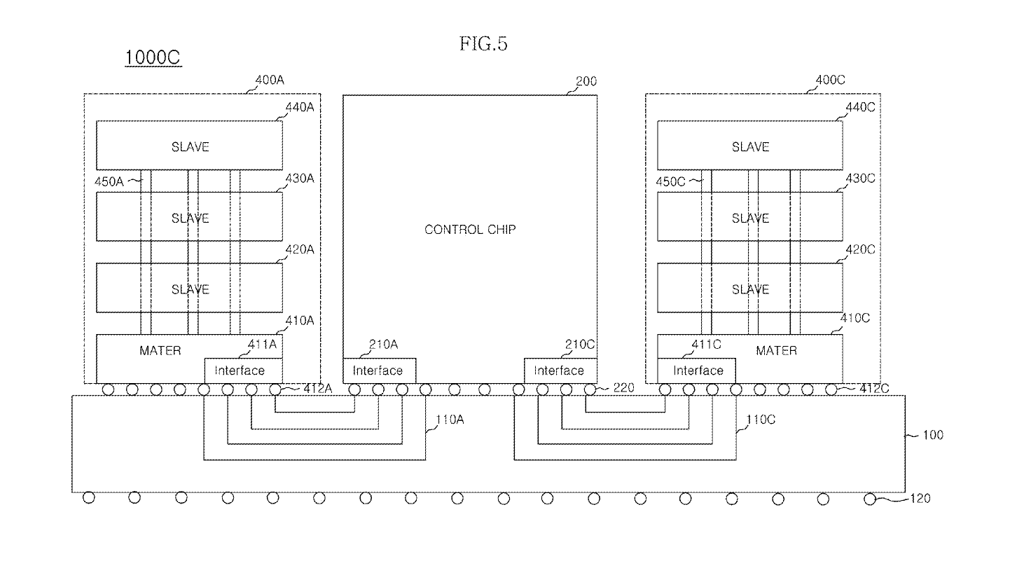

FIG. 5 is a cross-sectional view illustrating the structure of a system package according to another exemplary embodiment.

The system package 1000C includes an interposer 100, a control chip 200, a first memory chip 400A, and a second memory chip 400C. The first memory chip 400A includes a plurality of chips 410A to 440A stacked on top of each other in a vertical direction, and the second memory chip 400C includes a plurality of chips 410C to 440C stacked on top of each other in a vertical direction. FIG. 5 shows two memory chips 400A and 400C, but this is only illustrative. The system package may include more than two memory chips.

The interposer 100 may be a component for electrically connecting heterogeneous chips to form one semiconductor package. The interposer 100 may electrically connect the control chip 200 and the first and second memory chips 400A and 400C which are mounted thereon. In one embodiment, the interposer 100 may include a silicon chip serving an interface function and having metal interconnects without a semiconductor circuit. Furthermore, the interposer 100 may include a silicon chip used as an interface and a specific logic circuit. The interposer 100 may be electrically connected to an external circuit through one or more bumps 120, for example.

The control chip 200 may be a microprocessor or a memory controller configured to control the operation of the first and second memory chips 400A and 400C. In one embodiment, the control chip 200 may be positioned in a center area of the interposer 100. The control chip 200 may be coupled to the interposer 100 through micro bumps 220, for example.

The first and second memory chips 400A and 400C store data under the control of the control chip 200. The first and second memory chips 400A and 400C may be arranged over the interposer 100 so as to be distributed around the control chip 200, similar to the configurations in FIG. 2 or FIG. 3, or other suitable configurations. The first and second memory chips 400A and 400C may be coupled to the interposer 100 through micro bumps 412A and 412C, respectively.

The first and second memory chips 400A and 400C may have interface blocks 411A and 411C placed adjacent to the interface blocks 210A and 210C of the control chip 200. As described above, the interface blocks 210A, 210C, 411A, and 411C of the control chip 200 and the first and second memory chips 400A and 400C transmit and receive signals, and may include an input/output buffer, and an input/output pad for performing signal input/output operations.

FIG. 5 illustrates that the first and second memory chips 400A and 400C are arranged on the left and right sides of the control chip 200, but the system package 1000C may be configured in various other ways whereby two or more memory chips are distributed around the control chip in such way that the power dissipation associated with signal transmissions at the interface blocks is distributed.

However, it is desirable that the first and second memory chips 400A and 400C are configured to be vertically symmetrical with respect to the control chip 200 as illustrated in FIG. 5. The symmetrical configuration ensures that similar chips positioned on the left and right sides of the control chip operate similarly and with the same operational characteristics, and the semiconductor chips may be efficiently arranged without an empty space in terms of design.

The interposer 100 may be configured to electrically connect the control chip 200 and the first and second memory chip 400A and 400C. In one embodiment, the interposer may include conductive interconnect lines 110A and 110C which electrically connect the control chip 200 to the first and second memory chips 400A and 400C, respectively. Specifically, the conductive interconnect lines 110A and 110C may electrically connect the interface blocks 411A and 411C of the memory chips 400A and 400C to the corresponding interface blocks 210A and 210C of the control chip 200, respectively.

In one embodiment, the first and second memory chips 400A and 400C may include master chips 410A and 410C and a plurality of slave chips 420A, 430A and 440A and 420C, 430C and 440C, respectively. The master chip 410A and the plurality of slave chips 420A to 440A may be vertically stacked and electrically connected through one or more though-chip vias 450A, and the master chip 410C and the plurality of slave chips 420C to 440C may be vertically stacked and electrically connected through one or more through-chip vias 450C. FIG. 5 illustrates that the memory chips 400A and 400C include three slave chips 420A to 440A and 420C to 440C, respectively, but fewer or more slave chips may also be used.

The master chips 410A and 410C inside the respective memory chips 400A and 400C serve to exchange signals with the control chip 200 and control the slave chips 420A to 440 and 420A to 440C, respectively. The slave chips 420A to 440A and 420C to 440C perform a specific function under the control of the master chips 410A to 410C, respectively. For example, the master chips 410A and 410C are provided with peripheral circuits related to signal input/output and control signals, and the slave chips 420A to 440A and 420C to 440C are provided with memory banks for storing data.

According to some embodiments, the master chips 410A and 410C may include the interface blocks 411A and 411C that are located in corners adjacent to the control chip 200, respectively. The interface blocks 411A and 411C may be electrically connected to the control chip 200 through the respective conductive interconnect lines 110A and 110C formed over the interposer 100.

While the present invention has been shown and described with reference to exemplary embodiments thereof, it will be understood by those of ordinary skill in the art that various changes in form and details may be made therein without departing from the spirit and scope of the present invention.

What is claimed is:

1. A system package comprising:
an interposer;
a control chip mounted onto the interposer; and
first and second semiconductor chips mounted onto the interposer and electrically coupled to the control chip through the interposer, the first and second chips being configured to operate under the control of the control chip,
wherein the first semiconductor chip is positioned along one side of the control chip, and the second semiconductor chip is positioned along another side of the control chip.

2. The system package according to claim 1, wherein the first and second semiconductor chips comprise homogeneous semiconductor chips having similar functionality.

3. The system package according to claim 2, wherein the interposer comprises conductive interconnect lines to electrically connect the control chip to the first and second semiconductor chips.

4. The system package according to claim 3, wherein the control chip comprises first and second interface blocks formed in areas thereof which are adjacent to the first and second semiconductor chips, respectively, and the first and second interface blocks are respectively electrically connected to the first and second semiconductor chips through the conductive interconnect lines.

5. The system package according to claim 3, wherein the first and second semiconductor chips comprise interface blocks formed in areas thereof which are adjacent to the control chip, and
the interface blocks are electrically connected to the control chip through the conductive interconnect lines.

6. The system package according to claim 2, wherein the first and second semiconductor chips are positioned on opposite sides of the control chip.

7. The system package according to claim 2, wherein the first and second semiconductor chips comprise first and second memory chips, respectively.

8. The system package according to claim 7, wherein each of the first and second memory chips is divided into a plurality of channels each having an independent interface block.

9. A system package comprising:
an interposer;
a control chip mounted onto the interposer; and
a plurality of semiconductor chips mounted onto the interposer and configured to operate under the control of the control chip,
wherein the plurality of semiconductor chips are positioned along four sides of the control chip.

10. The system package according to claim 9, wherein the plurality of semiconductor chips comprise homogeneous semiconductor chips having the same function.

11. The system package according to claim 10, wherein the interposer comprises conductive interconnect lines to electrically connect the control chip to the plurality of semiconductor chips.

12. The system package according to claim 11, wherein the control chip comprises interface blocks formed in areas thereof adjacent to the respective semiconductor chips, and
the interface blocks are electrically connected to the semiconductor chips through the conductive interconnect lines.

13. The system package according to claim 11, wherein the plurality of semiconductor chips comprise interface blocks formed in areas thereof adjacent to the control chip, and the interface blocks are electrically connected to control chip through the conductive interconnect lines.

14. A system package comprising:
an interposer;
a control chip mounted onto the interposer;
a first memory chip mounted onto the interposer along one side of the control chip and comprising a plurality of memory chips stacked on top of one another in a vertical direction, the first memory chip being configured to operate under the control of the control chip; and
a second memory chip mounted onto the interposer along another side of the control chip and comprising a plurality of memory chips stacked on top of one another in a vertical direction, the second memory chip being configured to operate under the control of the control chip.

15. The system package according to claim 14, wherein the interposer comprises conductive interconnect lines configured to electrically connect the control chip to the first and second memory chips.

16. The system package according to claim 15, wherein the control chip comprises first and second interface blocks formed in areas thereof which are adjacent to the first and second memory chips, respectively, and the first and second interface blocks are respectively electrically connected to the first and second memory chips through the conductive interconnect lines.

17. The system package according to claim 15, wherein each of the first and second memory chips comprises:
a master chip configured to transmit and receive signals to and from the control chip through the conductive interconnect lines; and
a plurality of slave chips configured to perform operations under the control of the master chip, and
the master chip and the plurality of slave chips are stacked on top of one another in a vertical direction.

18. The system package according to claim 17, wherein the master chip and the slave chips are electrically connected by through-chip vias.

19. The system package according to claim 17, wherein the master chip included in each of the first and second memory chips comprises an interface block formed in an area thereof which is adjacent to the control chip, and
the interface block is electrically connected to the control chip through the conductive interconnect lines.

20. The system package of claim 17 wherein the master chip comprises peripheral circuitry, and the plurality of slave chips include memory banks, the peripheral circuitry being configured to provide access to the memory banks in the slave chips so that data can be stored in or retrieved from the memory banks.
